(19) United States
(12) Patent Application Publication
(10) Pub. No.: US 2023/0318653 A1
(43) Pub. Date: Oct. 5, 2023

(54) HOUSING COMPONENT OF A MOBILE TERMINAL

(71) Applicant: Carbon Mobile GmbH, Berlin (DE)

(72) Inventor: Firas Khalifeh, Berlin (DE)

(21) Appl. No.: 18/014,558

(22) PCT Filed: Jul. 9, 2021
(86) PCT No.: PCT/IB2021/056173

§ 371 Date: Jan. 5, 2023

(30) Foreign Application Priority Data
Jul. 11, 2020 (DE) 10 2020 118 348.8

(51) Int. Cl. H04B 1/3888; C08J 5/24; H01Q 1/24; H01Q 1/42; H01Q 1/36; H05K 9/00

(52) U.S. Cl. CPC H04B 1/3888; C08J 5/243; C08J 5/244; H01Q 1/243; H01Q 1/42; H01Q 1/36; H05K 9/0047; C08J 2300/22

(57) ABSTRACT

A housing component for a mobile terminal such as a smartphone or a laptop computer, includes a carbon fiber reinforced plastic body that is operative to shield components within the housing from electromagnetic radiation. The housing component further includes at least one antenna window. The at least one antenna window is configured to be associated with at least one antenna of the terminal. The at least one antenna window enables the at least one antenna to transmit and receive electromagnetic signals without being shielded or interfering with the operation of the terminal circuitry within the housing.

### TECHNICAL FIELD

Exemplary arrangements relate to a housing component for a mobile terminal with a transmitting and/or receiving device, such as a cell phone or a tablet computer. Exemplary arrangements relate to a housing component made of carbon fiber reinforced plastic that provides electromagnetic shielding and that includes an antenna window.

### DISCUSSION

For the production of mobile terminals with transmitting and/or receiving devices, such as cell phones or tablet computers, it is useful to manufacture the housing of the mobile terminal from carbon fiber reinforced plastic. The carbon fiber reinforced plastic has strength values similar to those of other types of molded parts made of cast aluminum/magnesium. A particular feature of the carbon fiber reinforced plastic is that it can absorb impacts, as is occasionally the case when a device is dropped from hand height, with the absorbed kinetic energy being dissipated in the carbon fiber composite and not passed on to other components. Another useful aspect of housings made of carbon fiber reinforced plastic is their low weight. Some types of cell phones, known as “smartphones,” may often weigh 200 g or more, which, when carried in an inside pocket of a suit jacket, can lead to undesirable distortion of the suit. The sometimes one-sided weight of the smartphone is also perceived as annoying. With folding smartphones, i.e. smartphones with a foldable display, the weight increases considerably because each molded part reaches about the weight of a single smartphone.

In international patent application WO 2017/202751 A1, which corresponds to U.S. Pat. No. 10,934,415 the disclosure of which is incorporated herein by reference in its entirety, polycarbonate compositions containing fillers, a carboxylic acid and glycerol or diglycerol esters thereof are disclosed, wherein the fillers are carbon fibers. Such a composite material is disclosed for use in constructing a thin wall application such as so-called ultrabooks or smartphones.

As a rule, applications of carbon fiber composites are characterized by their mechanical properties and their weight. A rather fashionable side effect of carbon fiber composites is the visibility of the carbon fiber scrim or fabric.

The use of carbon fiber composites has been found to have a useful side effect. Due to the high electrical conductivity of the carbon fibers, a housing wall for a cell phone, tablet computer or smartphone has a shielding effect like a Faraday cage. The effect is more pronounced the more directions in which the carbon fiber filaments are regularly laid. There are unidirectional carbon fiber composites, often referred to as UD composites. In unidirectional fabrics, the effect as a Faraday cage is less pronounced and the shielding is strongly dependent on the direction of lay in relation to the orientation of the antenna within the mobile terminal. Other influencing factors are the frequency of the electromagnetic radiation and also the propagation of the electromagnetic radiation as a dipole antenna. Even with a bidirectional fabric or a multilayer fabric with different directions of the filaments, the shielding effect as a Faraday cage increases strongly. In fabrics with few filaments, about 1,000 per strand, the shielding effect is so strong that electromagnetic signal transmission and reception through the material are no longer possible. Compared with another plastic composite material, carbon fiber composite material has the advantage that the electromagnetic radiation from the cell phone is strongly shielded. The shielding performance or the attenuation of the electromagnetic radiation is comparable to the attenuation of a housing made of aluminum and/or magnesium.

In order to operate a transmitting and receiving antenna in a mobile terminal, it is known in aluminum and/or magnesium housings to galvanically isolate one edge of the housing from the rest of the housing. The galvanically separated edge is used as an antenna for the transmission and receipt of electromagnetic signals of the mobile terminal. Such galvanic separation of an edge of a mobile terminal can be recognized externally by apparent design strips. In fact, however, the strips are made of plastic or glass to provide the galvanic isolation.

A comparable design of a housing made of carbon reinforced plastic is not possible, however.

It is therefore useful to provide a housing component including a molded part for use as part of a housing of mobile devices that is made of carbon fiber reinforced plastic, which enables operation of a transmitting and receiving antenna within the mobile device. In exemplary arrangements the housing component includes at least one antenna window. In exemplary arrangements an antenna window may comprise a window portion of a different plastic material that does not shield electromagnetic radiation that is in fixed connection by being inserted into the carbon fiber reinforced molded part or that is formed as an opening into which an insert antenna is positioned. Alternative antenna windows may include an electrically insulating connecting portion of the housing component that isolates an antenna from the carbon fiber of the carbon fiber reinforced plastic.

In exemplary arrangements, it is intended, in contrast to known moldings for housings of transmitting mobile terminals, to incorporate an antenna window into the molded housing component. The exemplary molded housing component thus consists of at least two different materials, whereby in an advantageous exemplary arrangement the material of the antenna window may also be a fiber composite material. Fiber reinforced plastics in fact have a pronounced anisotropy with regard to fracture propagation within their microstructure. In order to prevent a mechanical shock wave from building up at the junction between the different materials due to an abrupt change in mechanical properties, such as local modulus of elasticity or shear modulus, in the event of a mechanical impact on the housing of the mobile terminal, for example by dropping, in such a way that a crack is formed at the junction line between the different materials, it can be provided that the antenna window is made of glass fiber or other fiber reinforced plastic. In some arrangements the glass fibers may be laid in the identical direction as the carbon fibers or woven with the same pattern. Although the mechanical properties are different between carbon fiber reinforced plastic and glass or other fiber reinforced plastic, the anisotropy of the local mechanical properties of the different fiber reinforced materials is comparable. A mechanical shock wave propagates more uniformly when passing from one material to the other. If the antenna window formed as an antenna window portion in which an antenna is inserted or embedded, a plastic material which electrically isolates the antenna from the carbon fiber forms the second material of the antenna window.

In order to increase the electromagnetic attenuation of the body material in the area of the carbon fiber reinforced plastic, and at the same time to make the isotropy of the mechanical shock wave propagation more uniform, it can be provided that the carbon fiber reinforced plastic in some arrangements may comprise a multi-axial carbon fabric. On the other hand, in some arrangements the antenna window can be made of glass fiber reinforced plastic to adjust the shock wave propagation.

In some exemplary arrangements in order to increase stability in the region of the junction of the carbon fiber reinforced plastic and the antenna window and to reduce a tendency to break along the junction line in the event of an impact, it may be provided that the junction between the carbon fiber reinforced plastic and the antenna window may include interengaging projections and recesses, for example the body may include a recess therein formed as an undercut, wherein a negative shape of the undercut in the carbon fiber reinforced plastic corresponds to a positive shape projection within the undercut on the antenna window. Further in exemplary arrangements the joint between the carbon fiber reinforced plastic and the antenna window is covered with an overmold layer of plastic on at least one transverse side.

The interengagement of the undercut ensures that the different materials are joined in fixed engagement and interlock tightly. Overmolding a plastic layer that extends over a part of the body portion and a part of the window portion and which can be applied to the housing component in the injection molding process, ensures the positive mold and the negative mold of the undercut are positively connected by engagement with one another and the overmold layer before lateral breakout.

For further stabilization of the connection between the carbon fiber reinforced plastic body portion and the antenna window portion, it can be provided that the connection between the carbon fiber reinforced plastic body and the antenna window is designed as an overlap in which one of the body and the window is in overlying relation with the other. For this purpose in some arrangements, the carbon fiber reinforced plastic body may be reduced to about half its wall thickness by milling. The antenna window can be formed and held in fixed connection with the body by applying a prepreg and pressing under heat or by applying a thermoplastic and glass fiber reinforced plastic to the milled surface.

As an alternative to an antenna window that extends through the entire housing component wall and that is permeable to electromagnetic radiation, an antenna window portion may be incorporated in a first side of a wall of the carbon fiber reinforced body portion that extends to a reduced thickness such as about half the surrounding wall thickness. The first side is configured to serve as an external side of the terminal housing. To utilize the antenna window portion, an antenna can be incorporated in the window portion, which has an electrical connection through the carbon fiber reinforced wall to connect the antenna to electronics located on a second side of the molded body of the housing component, that is configured to be on an internal side of the terminal housing when the terminal is assembled.

In an exemplary arrangement it may be provided that the antenna window portion is embedded in the surface of the first side of the molded body made of carbon fiber reinforced plastic. In this arrangement an antenna such as a coil antenna made of carbon fibers is positioned within the antenna window portion. Carbon fibers have a specific electrical conductivity comparable to metallic electrical conductivity, and optionally the conductivity of carbon fibers is even higher. Carbon fibers of the exemplary antenna may be sheathed with or otherwise surrounded by thermoplastic resin to bond them to the resin and bonding them together during compression under heat. This sheathing results in a shell providing good electrical insulation of the individual carbon fibers of the antenna. If the carbon fibers and the shell are now placed in the embedded antenna window portion like a coil antenna, and if the ends of the carbon fibers are passed through the fabric or scrim of the carbon fibers which reinforce the plastic of the body, the organic carbon antenna can be used like a metallic antenna. The use of an organic carbon fiber antenna in some arrangements has the further advantage that the body component is completely transparent to X-rays. Cell phones, smartphones, tablet computers can thus be better screened during a routine inspection at the airport or in other security areas. For the construction of the molded part of the body including carbon fiber reinforced plastic, it can be provided in some arrangements that the molded body has a multi-layer multi-axial carbon fabric (fabric made of carbon fibers). In an exemplary antenna window portion in which a coil is inserted as a coil antenna made of carbon fibers, the ends of the carbon fibers of the coil antenna may be passed through the multi-axial carbon fabric to the second side. The multilayer carbon fabric shields the electronics present on the second side inside the molded body of the housing component from the transmitting power of the electromagnetic signals output by the antenna.

In a further, alternative arrangement of the molded body part, it can be provided that an insert antenna is arranged in the region of the antenna window. In such an arrangement the antenna is separated by an electrically insulating connecting portion from the carbon fibers of the body. The connecting portion and the antenna is connected to the molded body by overmolding the carbon fiber reinforced plastic. Thus, according to this optional exemplary arrangement, it is provided that the molded body part is equipped with an insert antenna, wherein the insert antenna is on the first side and can transmit and receive electromagnetic signals through the antenna window.

The density of the carbon fibers and the density of the meshes of the fabric have an influence on the shielding effect against electromagnetic radiation in the range from 800 MHz to 4 GHz. Fabrics woven with 1,000 fibers per strand, with 3,000 fibers per strand, and with 12,000 fibers per strand have been found to be useful in exemplary arrangements. Such carbon fiber fabrics are commercially available as 1 K (1,000 fibers/filaments), 3K (3,000 fibers/filaments), and 12 K fabrics (12,000 fibers/filaments). The molded part of the body can be made in exemplary arrangements by compressing a prepreg in a mold or from hot forming a thermoplastic and carbon fiber reinforced plastic or from fibers already coated with a thermoplastic.

In an exemplary arrangement the molded part of the body of the terminal housing component may have a side wall on a first side of the molded body that comprises an antenna window. The window includes an electrically insulating connecting portion of the housing component. Metallic high-performance antenna may be positioned, wherein the material of the connecting portion of the antenna window galvanically separates the metallic high-performance antenna from the carbon fiber of the carbon fiber reinforced plastic body.

Exemplary arrangements are explained in more detail in the following Detailed Description.

### BRIEF DESCRIPTION OF DRAWINGS

FIG. 1 is a back view of a molded part of a smartphone housing from the PRIOR ART, here as a one-piece mold of a housing shell.

FIG. 2 is a plan view of a housing component including a molded body made of carbon fiber composite material with a recessed antenna window.

FIG. 3A is a transverse sectional view of an exemplary joint between carbon fiber composite body and an antenna window.

FIG. 3B is a longitudinal sectional view of the joint of FIG. 3A.

FIG. 4 is a plan view of a housing component with an embedded antenna in a window portion and a carbon fiber antenna.

FIG. 5 is an enlarged sectional view along line A-A in FIG. 4.

FIG. 6 is a plan view of the second side of a further alternative housing component configured to have an alternative antenna window including an electrically insulating connection portion.

FIG. 7 is a plan view of an exemplary antenna.

FIG. 8 is a perspective view of the antenna shown in FIG. 7.

FIG. 9 is a plan view of the second side of the housing component of FIG. 6 with an antenna window that includes an electrically insulating connecting portion which electrically isolates the antenna from the carbon fiber of the body.

FIG. 10 is a plan view of the first side of the housing component according to the arrangement of FIG. 9, which first side corresponds to an external side of the terminal housing.

FIG. 11 shows a detail of the side wall of an exemplary housing component with an undercut.

FIG. 12 shows the detail from FIG. 11, in which the need for the undercut has been avoided by overmolding.

FIG. 13 is a plan view of an alternative housing component with a molded carbon fiber composite body, a dual antenna window and a high-power antenna.

FIG. 14 is a plan view of a second side of a housing component including a circuit board, antenna window and an antenna.

### DETAILED DESCRIPTION

FIG. 1 shows a molded part of a known smartphone housing. The molded part has a monocoque structure, which means that it is single-shell and has only a single wall material. The molded part has been produced by known pressing of a prepreg in a mold. Prepregs are fabric mats impregnated with a partially polymerized plastic. The partially polymerized plastic is epoxy resin or a vinyl ester. These are flexible when cold and can be laid in a mold. When hot pressed in a mold, the bonding plastic polymerizes, forming a solid piece with a generally thin wall.

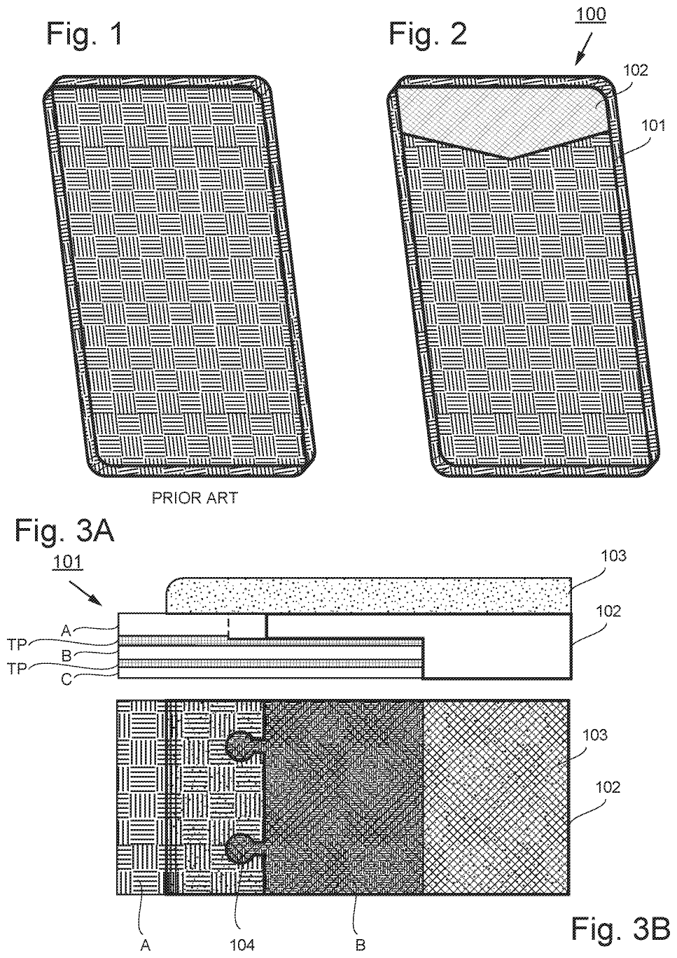

FIG. 2 shows a housing component 100 according to an exemplary arrangement configured for use as part of a housing of a mobile terminal such as a smartphone or tablet computer. This exemplary housing component 100 consists of two materials. The predominant part of the housing component comprises a carbon fiber reinforced plastic body 101, which may be produced by pressing a prepreg with epoxy resin, with melamine resin or with a vinyl ester resin. Thermoplastic materials may also be used, with the individual carbon fibers being sheathed with a thermoplastic material. Only when the fabric is pressed in a mold under heat does the carbon fiber reinforced molded body form, with the sheaths of adjacent carbon fibers fusing together. In this arrangement the housing component further includes an antenna window 102. In this exemplary arrangement the antenna window comprises a window portion with a wall thickness that is formed in the housing component. In this regard, the exemplary antenna window 102 may be a window portion comprised of glass fiber reinforced epoxy resin, for example, or another plastic that does not prevent electromagnetic radiation from passing therethrough. The exemplary antenna window 102 is positioned at one end of an upright housing component. At this location, in some smartphones, cell phones and/or tablet computers, an antenna for transmitting and receiving signals comprising electromagnetic radiation such as radio signals for communication with remote transmitting and receiving towers may be positioned. In order to match the local mechanical properties of the carbon fiber reinforced plastic body 101 and the glass fiber reinforced epoxy resin of the antenna window 102 in this case, it may be provided that the orientation of the fabric fibers of both types of plastics is aligned.

In FIGS. 3A and 3B, a joint between the carbon fiber reinforced plastic body 101 and the antenna window 102 in FIG. 2 is shown along the joint edge between the carbon fiber reinforced plastic body 101 and the antenna window 102. In this exemplary arrangement, the carbon fiber reinforced plastic body 101 comprises three layers A, B, and C, which are provided with carbon fiber fabrics of a different bidirectional mesh density. The different layers A, B and C are bonded together via a thermoplastic material TP. Here, the innermost layer A comprises, for example, a carbon fiber reinforced plastic with a carbon fiber fabric with 12,000 carbon fibers per woven strand, which corresponds to a so-called 12K fabric. The middle layer B, for example, comprises a carbon fiber reinforced plastic with a carbon fiber fabric with 3,000 carbon fibers, which corresponds to a so-called 3K fabric. The outermost layer C, for example, comprises a carbon fiber reinforced plastic with a carbon fiber fabric with 1,000 carbon fibers per woven strand, which corresponds to a so-called 1K fabric. To join the carbon fiber reinforced plastic body 101 to the antenna window 102, which in this example arrangement is made of a glass fiber reinforced plastic material, the molded body is removed in the area of the edge of the carbon fiber reinforced plastic body 101 to such an extent that the layer thickness is only about half the total wall thickness of the housing component 100, although part of the thermoplastic material TP joining the layers A and B is left. This thermoplastic material TP connecting layers A and B serves as a connecting surface between the carbon fiber reinforced plastic and the glass fiber reinforced plastic of the antenna window 102. In this example arrangement, a glass fiber reinforced plastic lies on the forming tongue of the carbon fiber reinforced plastic body 101 with about half the wall thickness. The exemplary body and window portion include interengaging projections and recesses. This includes individual undercuts 104 which protrude like pegs from the glass fiber reinforced plastic of the antenna window 102 and, when a prepreg is pressed, pour into corresponding and milled negative shapes of the undercuts 104. When the prepreg of the glass fiber reinforced plastic for the antenna window portion 102 is pressed, the epoxy resin of the glass fiber reinforced plastic of the antenna window 102 bonds with the carbon fiber reinforced plastic of the body 101 of the housing component. To prevent the undercuts from breaking out of the negative molds, an overmold layer 103 is provided, which is applied to the bonding edge of the two different materials during molding by an injection molding system. The overmold layer of this exemplary arrangement overlies and is bonded to at least a part of the body portion and at least a part of the window portion. Of course it should be understood that this approach is exemplary.

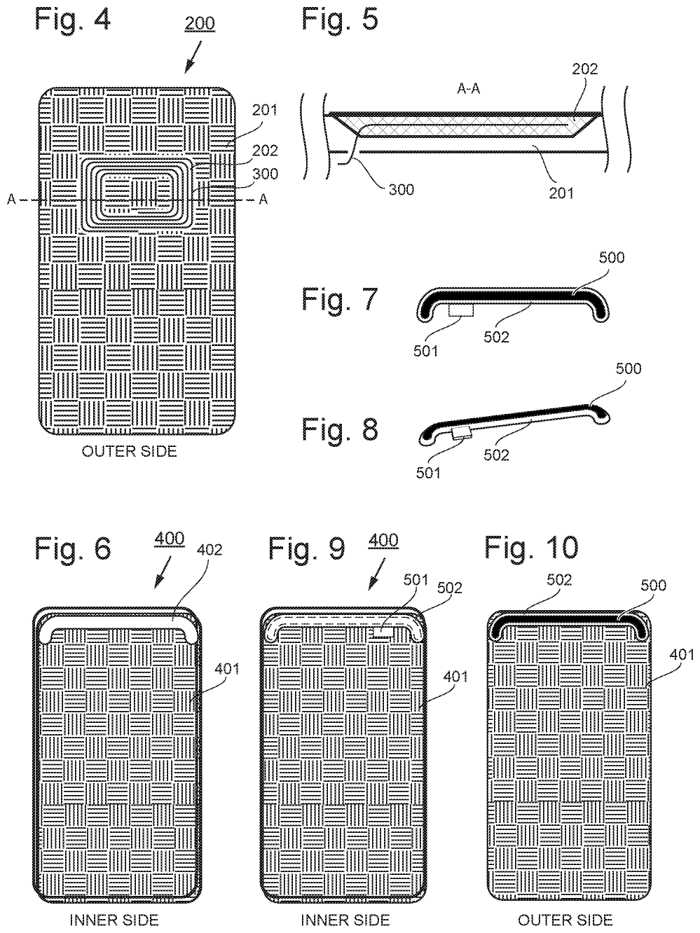

FIG. 4 shows an alternative arrangement of a housing component which comprises a housing component 200. In this exemplary arrangement, an antenna window 202 that comprises a window portion is embedded in a surface that bounds the external side of the carbon fiber reinforced plastic body 201. In this case, the electromagnetic radiation shielding layer of the body underlying the window portion is only about half as thick as the wall thickness of the body 201 in areas away from the window portion. In this case, the antenna window 202 has an embedded antenna 300, which may in some arrangements also be made of carbon fibers. In the exemplary case of the carbon fiber antenna, the ends of the individual fibers which comprise the antenna are passed through the fabric of the carbon fiber reinforced plastic body 201 so that the ends can be connected to appropriate drive electronics and circuitry on an opposed side which corresponds to the internal side of the terminal housing. To illustrate the location of the exemplary embedded antenna 300, a view of cut line A-A in FIG. 4 is shown in FIG. 5. The antenna 300, which may comprise individual carbon fibers, is embedded in the window portion of the antenna window 202, with the antenna window 202 window portion itself embedded in the carbon fiber reinforced plastic body portion 201. The embedding can be achieved by folding together a prepreg for pressing the carbon fiber reinforced plastic body 201 and an antenna 300, wherein when the folded prepregs are pressed together, the plastic portion of the prepregs of the carbon fiber reinforced plastic body 201 and the antenna 300 wraps around the individual carbon fibers in a correspondingly forming manner. In exemplary arrangements the carbon fibers which comprise the antenna are surrounded by a plastic that does not prevent electromagnetic radiation from passing through the window portion to and from the antenna while the underlying carbon fiber reinforced body portion underlying the window portion substantially prevents the electromagnetic radiation on the first side of the body from the antenna and other sources, from reaching the second side of the body which corresponds to the interior area of the device housing. When referred to herein substantially preventing the passage of electromagnetic radiation means the radiation that passes through does not interfere with the operation of circuitry in the terminal housing.

FIG. 6 shows a view of the inside of a still further exemplary arrangement of a housing component 400. The housing component 400 has a body 401 and an antenna window 402. The exemplary window comprises a recess in the housing component 400. This recess is configured to receive an insert antenna 500, which in an exemplary arrangement may be firmly connected to the body 401 by an overmold layer. For this purpose, the insert antenna 500 is placed in the region of the recess and antenna window 402 includes an electrically insulating connecting portion that is connected to the antenna and extends in intermediate insulating relation of the antenna and the carbon fibers of the carbon fiber reinforced plastic body 401. The exemplary antenna and connecting portion may be held in place by overmolding in an injection mold. In the exemplary arrangement, the insert antenna 500 protrudes from the housing component 400.

In FIG. 7, the exemplary insert antenna 500 is shown in a top view. An electrical connection 501 and an electrical insulation connecting portion which comprises body 502 for receiving the insert antenna 500 and for electrical insulation with respect to the carbon fibers of the body 401 can be seen from above. The same insert antenna 500 is shown in perspective in FIG. 8, the perspective view revealing the applicative shape of the insulation body 502. The exemplary insert antenna 500 shown here is shown together with the electrical insulation body 502. In some exemplary arrangements, the insert antenna 500 is bonded to the body 401 of housing component 400 by overmolding plastic in the mold, and the electrical insulation body 502 is formed during overmolding which provides an overmold layer.

FIG. 8 shows a perspective view of the exemplary insert antenna shown in FIG. 7. In an exemplary arrangement this insert antenna 500 is inserted with the narrower side facing into the recess of the antenna window 402 and connected to the body 401 of housing component 400 by overmolding. In the process, the electrical insulation body 502 which comprises the electrically insulating connecting portion of the antenna window is formed.

FIG. 9 shows a view of the inside of the housing component 400 from FIG. 6 with an insert antenna 500 molded in by overmolding. The exemplary electrical insulation body 502 serves as a connecting portion of the antenna window 402 and insulates the insert antenna 500 from the carbon fibers of the body 401 of the housing component 400. In this view, the insert antenna 500 is shown as a dashed line because the electrical insulation body 502 covers the insert antenna 500. Of course this antenna window and antenna configuration is exemplary and in other arrangements other configurations may be used.

FIG. 10 shows a view of the outside of the exemplary housing component 400 from FIG. 6 with the insert antenna 500 molded in by an overmold layer. The electrical insulation body 502 serves as a connecting portion of the antenna window and electrically insulates the insert antenna 500 from the carbon fibers of the body 401 of the housing component 400.

FIG. 11 shows a section through the exemplary housing component 100 in the region of a side wall 110. The exemplary carbon fiber reinforced plastic body 101 may be hot pressed in a mold. In order to have the surface of the housing component be flush with a display 111, it is necessary for the display to lie in an enclosure 112. This exemplary enclosure 112 can be formed in some arrangements by a folded down wall of the side wall 110 of the housing component, as shown in FIG. 10.

To avoid forming an undercut in the mold that would require a complex mold to demold, an exemplary enclosure 112′ can be injected into the edge of the housing component as an overmold layer 105. The exemplary enclosure 112′ leans against the inner wall of the housing component and forms a enclosure 105′ for a display 111 in the area of the upper wall edge of the side wall 110, as shown in FIG. 12. The enclosure 112′ enables the upper wall edge of the side wall 110 to be pressed in a mold without undercutting and to be easily demolded. Of course it should be understood that this approach is exemplary and in other arrangements other approaches may be used.

FIG. 13 shows another exemplary arrangement of a housing component 600 with a carbon fiber composite body 601 and a pair of antenna windows. The housing component includes an inset antenna window 602 and a high-power antenna 603. The high-power antenna 603 in an exemplary arrangement may be of metallic construction and may accept and transmit signals for communication of the mobile terminal with a remote transmission tower. In order to galvanically separate the high power antenna 603 from the carbon fibers of the electrically conductive carbon fiber reinforced plastic body 601, it is provided that the plastic material of the antenna window 602 serves an antenna window that electrically isolates, receives and encloses the high power antenna 603 in a side wall 604 of the housing component. In this example, the antenna window 602 serves as a first antenna window with an electrically insulating connecting portion with regard to antenna 603 as well as a second antenna window with a window portion that serves to enable the passage of electromagnetic radiation for lower power transmitting and receiving antennas, such as RFID antennas and antennas for near-field and mid-field communications which may be embedded in or underlying of the window portion. Of course it should be understood that this configuration is exemplary.

FIG. 14 shows the exemplary housing component 100 of FIG. 2, wherein a circuit board 106 is arranged in the interior housing area on a second side of housing component 100. The circuit board 107 includes circuitry that is connected to an antenna 107. The antenna 107 is arranged in the window portion of the antenna window 102 so that the antenna 107 can transmit and receive electromagnetic signals through the plastic that comprises the window portion without shielding.

Thus the exemplary arrangements described herein achieve improved operation, eliminate difficulties encountered in the use of prior devices, systems and methods, and attain the useful results described herein.

In the foregoing description certain terms have been used for brevity, clarity and understanding. However no unnecessary limitations are to be implied therefrom because such terms are used for descriptive purposes and are intended to be broadly construed. Moreover the descriptions and illustrations herein are by way of examples and the new and useful concepts are not limited to the exact features that have been shown and described.

It should be understood that features and/or relationships associated with one exemplary arrangement can be combined with features and/or relationships from another exemplary arrangement. That is various features and/or relationships from various arrangements can be combined into further arrangements. The new and useful scope of the disclosure is not limited only to the exemplary arrangements that have been shown or described herein.

Having described the features, discoveries and principles of the exemplary arrangements, the manner in which they are constructed and operated, and the advantages and useful results attained, the new and useful features, devices, elements, configurations, parts, combinations, systems, equipment, operations, methods, processes and relationships are set forth in the appended claims.

### REFERENCE LIST

| | | | |
|---|---|---|---|
| 100 | housing component | 400 | housing component |
| 101 | carbon fiber reinforced plastic | 401 | carbon fiber reinforced plastic |
| | body portion | | body portion |
| 102 | antenna window | 402 | antenna window |
| 103 | overmold layer | 404 | electrical connection |
| 104 | undercut | 500 | insert antenna |
| 105 | overmold layer | 501 | electrical connection |
| 105' | enclosure | 502 | electrical insulation body |
| 106 | board | 600 | housing component |
| 107 | antenna | 601 | carbon fiber reinforced plastic |
| 110 | side wall | | body portion |
| 111 | display | 602 | antenna window |
| 112 | enclosure | 603 | high power antenna |
| 112′ | enclosure | 604 | side wall |
| 200 | housing component | A | layer |
| 201 | carbon fiber reinforced plastic | TP | thermoplastic material |
| | body portion | B | layer |
| 202 | antenna window | C | layer |
| 300 | coil antenna | | |

1-11. (canceled)

12. Apparatus comprising:
a housing component configured for use as part of a housing of a mobile terminal, wherein the mobile terminal
is operative to at least one of send and receive electromagnetic signals, and includes at least one antenna,
wherein the housing component comprises
a body
wherein the body
is comprised of molded carbon fiber reinforced plastic, wherein the carbon fiber reinforced plastic is operative to substantially prevent electromagnetic radiation on a first side of the body that is configured to be on an external side of the terminal housing, from reaching a second side of the body configured to be on an internal side of the terminal housing,
at least one antenna window, wherein the at least one antenna window comprises at least one of
a window portion,
wherein the window portion is comprised of a further plastic and is in fixed operative connection with the body, wherein the further plastic of the window portion does not prevent electromagnetic radiation on the first side from passing through the window portion,
whereby the window portion is configured to enable the at least one antenna to be positioned at least one of within the window portion or in aligned relation with the window portion, and
an electrically insulating connecting portion of the housing component,
wherein the connecting portion is in fixed connection with the body and extends on the first side in intermediate insulating relation between the at least one antenna and the carbon fiber of the body,
whereby the connecting portion is configured to enable the at least one antenna to be exposed to electromagnetic radiation on the first side.

13. The apparatus according to claim 12
wherein the housing component comprises both a window portion and an electrically insulating connecting portion,
whereby the window portion is configured to enable a first antenna to at least one of send and receive electromagnetic signals, and the connecting portion is configured to enable a second antenna that is different from the first antenna and in fixed connection with the connecting portion, to at least one of send and receive electromagnetic signals.

14. The apparatus according to claim 12
wherein the at least one antenna window comprises a window portion,
wherein the further plastic of the window portion comprises a fiber reinforced further plastic.

15. The apparatus according to claim 12
wherein the at least one antenna window comprises a window portion,
wherein the further plastic of the window portion comprises a further fiber reinforced further plastic,
wherein the housing component comprises the further fiber reinforced further plastic of the window portion and the molded carbon fiber reinforced plastic in fixed integrally molded connection.

16. The apparatus according to claim 12
wherein the at least one antenna window comprises a window portion,
wherein the window portion comprises one of an interengaging projection or recess, and
wherein a body portion of the body immediately adjacent to the window portion and comprised of carbon fiber reinforced plastic, includes the other of the projection or recess,
wherein the projection and recess are in joined molded interengaged relation.

17. The apparatus according to claim 12
wherein the at least one antenna window comprises a window portion,
wherein the window portion comprises one of an interengaging projection or recess, and
wherein a body portion of the body immediately adjacent to the window portion and comprised of carbon fiber reinforced plastic, includes the other of the projection or recess,
wherein the projection and recess are joined by interengagement of the projection and recess and by engagement with an overmold layer of plastic that extends across at least part of the body portion and at least part of the window portion.

18. The apparatus according to claim 12
wherein the at least one antenna window comprises a window portion,
wherein a body portion of the body immediately adjacent to the window portion and comprised of carbon fiber reinforced plastic, is in abutting relation with the window portion,
wherein the window portion and body portion are joined by engagement with an overmold layer of plastic that extends across at least part of the body portion and at least part of the window portion.

19. The apparatus according to claim 12
wherein the at least one antenna window comprises a window portion,
wherein the window portion is in fixed connection with an immediately adjacent body portion of the body comprised of molded carbon fiber reinforced plastic, by one of the window portion or the body portion being in molded overlying relation of the other of the window portion or the body portion.

20. The apparatus according to claim 12
wherein the at least one antenna window comprises a window portion,
wherein the window portion is in fixed outwardly overlying connection with an immediately adjacent body portion of the body comprised of molded carbon fiber reinforced plastic,
wherein the window portion outwardly overlies the body portion on the first side.

21. The apparatus according to claim 12
wherein the at least one antenna window comprises a window portion,
wherein the window portion is in fixed outwardly overlying connection with an immediately adjacent body portion of the body comprised of molded carbon fiber reinforced plastic,
wherein the window portion outwardly overlies the body portion on the first side and has the at least one antenna embedded within the further plastic of the window portion.

22. The apparatus according to claim 12
wherein the at least one antenna window comprises a window portion,
wherein the window portion is in fixed outwardly overlying connection with an immediately adjacent body portion of the body comprised of molded carbon fiber reinforced plastic,
wherein the window portion outwardly overlies the body portion on the first side and has the at least one antenna embedded within the further plastic of the window portion,
wherein the at least one antenna comprises a coil antenna comprised of carbon fiber.

23. The apparatus according to claim 12
wherein the at least one antenna window comprises a window portion,
wherein the window portion is in fixed outwardly overlying connection with an immediately adjacent body portion of the body comprised of molded carbon fiber reinforced plastic,
wherein the window portion outwardly overlies the body portion on the first side and has the at least one antenna embedded within the window portion,
wherein the at least one antenna comprises a coil antenna comprised of carbon fiber, wherein the body portion comprises multi-axial carbon fabric,
wherein carbon fiber ends of the coil antenna pass through the multi-axial carbon fabric.

24. The apparatus according to claim 12
wherein the at least one antenna window comprises an electrically insulating connecting portion,
wherein the body comprises a recess that extends inwardly on the first side,
wherein the electrically insulating connecting portion extends intermediate of the at least one antenna and the recess.

25. The apparatus according to claim 12
wherein the at least one antenna window comprises an electrically insulating connecting portion,
wherein the body comprises a recess that extends inwardly on the first side,
wherein a plastic overmold layer that extends in overlying relation of the recess includes the electrically insulating connecting portion.

26. The apparatus according to claim 12
wherein the at least one antenna window comprises an electrically insulating connecting portion,
wherein the body comprises a recess,
wherein a plastic overmold layer that extends on the first side in outwardly overlying relation of the recess includes the electrically insulating connecting portion,
wherein the plastic overmold layer outwardly overlies the at least one antenna on the first side.

27. The apparatus according to claim 12
wherein the body comprises a plurality of layers of carbon fiber fabric, wherein the layers are bonded together by a thermoplastic material.

28. The apparatus according to claim 12
wherein the body comprises a plurality of layers of carbon fiber fabric, wherein each layer has a different bidirectional mesh density, wherein the layers are bonded together by a thermoplastic material.

29. The apparatus according to claim 12
wherein the body comprises a plurality of layers of carbon fiber fabric of different bidirectional mesh density,
wherein a first layer comprises a carbon fiber fabric with 12,000 carbon fibers per woven strand,
wherein a second layer comprises a carbon fiber fabric with 1000 carbon fibers per woven strand,
wherein a third layer that extends intermediate of the first layer and the second layer comprises a carbon fiber fabric with 3000 carbon fibers per woven strand, wherein the plurality of layers are bonded together by a thermoplastic material.

30. The apparatus according to claim 12
wherein at least one of the further plastic and the electrically insulating connecting portion is comprised of glass fiber reinforced plastic.

31. The apparatus according to claim 12
wherein the body is comprised of at least one of a formed prepreg and a plurality of carbon fiber filaments coated with thermoplastic.

32. The apparatus according to claim 12 and further comprising:
a circuit board, wherein the circuit board is positioned on the second side and is disposed away from the at least one antenna window.

33. Apparatus comprising:
a housing component configured for use as part of a housing of a mobile terminal that includes at least one antenna that is usable to send and receive electromagnetic signals,
wherein the housing component includes
a body,
wherein the body is comprised of molded carbon fiber reinforced plastic, wherein the carbon fiber reinforced plastic is operative to substantially prevent electromagnetic radiation from passing from a first side of the body that is configured to be on an external side of the terminal housing, from reaching the second side of the body that is configured to be on an internal side of the terminal housing,
at least one antenna window,
wherein the at least one antenna window comprises at least one of
a window portion that is in fixed molded connection with the body and is comprised of a further plastic that does not prevent passage of the electromagnetic signals through the window portion, and
an electrically insulating connecting portion that is in fixed molded connection with the body and extends on the first side and is configured to be in intermediate insulating relation between the at least one antenna and the carbon fiber of the body,
whereby the at least one antenna is enabled to communicate electromagnetic signals while being embedded within or positioned in underlying aligned relation with the at least one window portion, or while being in insulated relation from the carbon fiber of the body by the electrically insulating connecting portion.

34. Apparatus comprising:
a housing component configured for use as part of a housing of a mobile terminal, wherein the mobile terminal includes at least one antenna that is useable for sending and receiving electromagnetic signals,
wherein the housing component comprises:
a body, wherein the body includes
a body portion comprised of molded carbon fiber reinforced plastic that is operative to substantially prevent electromagnetic radiation on a first side of the body portion that is configured to be on an external side of the terminal housing, from reaching a second side of the body portion which is configured to be internal side of the terminal housing,
at least one antenna window,
wherein the at least one antenna window is in fixed connection with the body portion and comprises at least one of
a window portion comprised of a further plastic through which the electromagnetic signals may pass, and
an electrically insulating connecting portion, that is configured to electrically insulate the at least one antenna from the carbon fiber.
